(19) United States
(12) Patent Application Publication
(10) Pub. No.: US 2026/0198279 A1
(43) Pub. Date: Jul. 9, 2026

(54) METHODS FOR FORMING LOW RESISTIVITY CONTACTS

(71) Applicant: Applied Materials, Inc., Santa Clara, CA (US)

(72) Inventors: Junyeong YUN, Santa Clara, CA (US); Kyoung-Ho BU, Pleasanton, CA (US); Changhyun CHOI, Santa Clara, CA (US); Wei LEI, San Jose, CA (US); Ju Hyun OH, San Jose, CA (US)

(21) Appl. No.: 19/009,606

(22) Filed: Jan. 3, 2025

(51) Int. Cl. H01L 21/768; C23C 16/04; H01L 21/02; H01L 23/532

(52) U.S. Cl. CPC H10W 20/098; C23C 16/045; H10P 14/6336; H10P 14/6339; H10P 14/69394; H10W 20/48

(57) ABSTRACT

The present disclosure generally provides methods of forming contact structures on semiconductor substrates. A metal layer is formed on a surface of a contact structure by maintaining a first temperature of a substrate and providing a first carrier gas, a first metal-containing precursor, and a first hydrogen-containing precursor to a first deposition chamber. The contact structure includes a feature. The feature includes an opening with a bottom surface and sidewalls, which comprise a dielectric material. The metal layer is formed over the sidewalls and the bottom surface and the metal layer comprises a metal and a silicon containing material. The metal layer is exposed to a metal chloride containing precursor to remove a top portion of the metal layer from the sidewalls. A metal gap fill material is deposited over the metal layer to fill the feature formed in the surface of the semiconductor substrate.

### FIELD

Embodiments disclosed herein generally relate to methods for forming low resistivity contacts for semiconductor device formation.

### BACKGROUND

Integrated circuits have evolved into complex devices that can include billions of transistors, capacitors, and resistors on a single chip. In the course of integrated circuit evolution, functional density (that is, the number of interconnected devices per chip area) has generally increased while geometry size (that is, the smallest component (or line) that can be created using a fabrication process) has decreased.

Microelectronic devices are fabricated on a semiconductor substrate as integrated circuits in which various conductive layers are interconnected with one another to permit electronic signals to propagate within the device. Examples of such devices include memory (for example, DRAM (dynamic random access memory)) and logic devices, including both planar and three-dimensional structures. Three-dimensional structures include finFET (fin field-effect transistor) or MOSFET (metal- oxide-semiconductor field-effect transistor) devices.

An example of a finFET or MOSFET device includes a gate electrode on a gate dielectric layer on a surface of a semiconductor substrate. Source/drain regions are provided along opposite sides of the gate electrode. The source and drain regions are generally heavily doped regions of the semiconductor substrate. Usually a silicide layer, for example a titanium silicide layer, is required to form a reliable contact at the formed source and drain regions.

In a traditional contact junction formation process, a feature also referred to as a cavity, a via, or a trench, is fabricated in the semiconductor substrate. In one example, middle-of-the-line (MOL) contact junctions allow connections between front-end-of-the-line (FEOL) semiconductor structures and back-end-of-the-line (BEOL) interconnects. Contacts with a low resistivity are desirable in semiconductor devices. However, when MOL contacts have high resistance, the contacts produce poor connections between the FEOL structures and the BEOL packaging interconnects, reducing the performance of the packaged semiconductor structures.

In traditional contact formation processes, a conformal titanium silicide (TiSi) layer is formed on a silicon or silicon germanium connection as a capping layer and then nitrided to form titanium silicon nitride (TiSiN) to prevent oxidation of the TiSi. The final silicide capping layer is a bilayer of TiSi and TiSiN that is formed over the field, sidewalls and contact regions formed on the substrate. The inventors have observed, however, that the TiSiN layer has a high resistivity (approximately 300μohms-cm for a thickness of approximately 6 nm). The TiSi(N)/W on the field and sidewall then need to be removed by a wet pull-back process, where physical vapor deposition (PVD) tungsten (W) only remains at the bottom of the via. Due to PVD technology limitations, it is challenging to deposit a continuous PVD W film at the high sloped area of the capping layer. Once the pull-back process has been completed, a selective metal deposition process (e.g., tungsten or molybdenum deposition process) can either partially or fully fill up the via. For example, a feature is filled with a low resistivity metal, either by cobalt (Co), molybdenum (Mo), or tungsten (W). Such an integration flow not only has high resistivity due to the TiSi/TiSiN bilayer, but also high cost due to the expensive thick FFW ALD deposition process and the pull-back process for thick TiN/PVD W.

Therefore, there is a need for improved methods to reduce contact resistance and simplified processes of forming low resistance contacts.

### SUMMARY

In an embodiment, the present disclosure provides methods of forming contact structures on a semiconductor substrate. A metal layer is formed on a surface of a contact structure by maintaining a first temperature of a substrate and providing a first carrier gas, a first metal-containing precursor, and a first hydrogen-containing precursor to a first deposition chamber. The contact structure includes a feature formed in a surface of the semiconductor substrate. The feature includes an opening that is defined by a bottom surface and sidewalls, which comprise a dielectric material. The metal layer is formed over the sidewalls and the bottom surface and the metal layer comprises a metal and a silicon containing material. The metal layer is exposed to a metal chloride containing precursor to remove a top portion of the metal layer from the sidewalls. A metal gap fill material is deposited over the metal layer to fill the feature formed in the surface of the semiconductor substrate.

In another embodiment, the present disclosure provides methods of forming contact structures on a semiconductor substrate. A metal layer is formed on a surface of a contact structure by maintaining a first temperature of a substrate and providing a first carrier gas, a first metal-containing precursor, and a first hydrogen-containing precursor to a first deposition chamber. The contact structure includes a feature formed in a surface of the semiconductor substrate. The feature includes an opening that is defined by a bottom surface and sidewalls, which comprise a dielectric material. The metal layer is formed over the sidewalls and the bottom surface and the metal layer comprises a metal and a silicon containing material. The metal layer formed over the sidewalls and the bottom surface are exposed to a nitrogen containing plasma to cause a portion of the metal layer to form a nitrided layer. The nitrided layer is exposed to a metal chloride containing precursor to remove a top portion of the nitrided layer from the sidewalls. A metal gap fill material is deposited over the nitrided layer to fill the feature formed in the surface of the semiconductor substrate.

### BRIEF DESCRIPTION OF THE DRAWINGS

Embodiments of the present principles, briefly summarized above and discussed in greater detail below, can be understood by reference to the illustrative embodiments of the principles depicted in the appended drawings found in the Appendix. However, the appended drawings illustrate only typical embodiments of the principles and are thus not to be considered limiting of scope, for the principles may admit to other equally effective embodiments.

FIG. 1 (Prior Art) is a cross-section view of a portion of a semiconductor structure, according to embodiments of the present disclosure.

FIG. 2 is a flow chart of a method of selective CVD TiSi deposition and TiSi/Mo integration, according to embodiments of the present disclosure.

FIGS. 3A, 3B, 3C, 3D, 3E, and 3F are cross-sectional views of a portion of a semiconductor substrate based on the method of FIG. 2, according to embodiments of the present disclosure.

FIG. 4 is a diagrammatic view of an integrated tool, according to embodiments of the present disclosure.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Methods of the present disclosure provide middle-of-the-line (MOL) contacts with reduced resistivity. Methods can integrate multiple MOL processes on the same integrated tool as well as achieve low contact resistance (Rc). For example, a process has been developed that forms a metal layer and nitrides the metal layer. The nitride metal layer is selectively etched by use of a selective etching process such that the deposition of a low resistance gap fill material is selective towards a bottom surface of the cavity, via, and/or trench, thereby reducing resistivity by preventing seam formation within the gap fill material

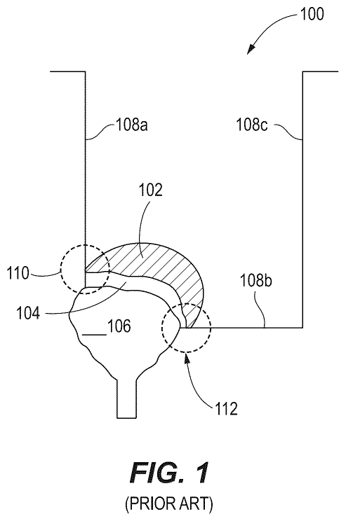

FIG. 1 is a schematic illustration of a structure 100 having a tungsten layer disposed on a capping layer. As shown in FIG. 1 (Prior Art), structure 100 has a metal layer 102, e.g., tungsten and/or molybdenum, which has been selectively deposited on a capping layer 104, e.g., a TiSi capping layer. Capping layer 104 is disposed on contact structure 106. For conventional selective deposition processes like that shown in FIG. 1, metal deposition selectivity is high on the capping layer, e.g., TiSi, instead of dielectric surfaces 108a, 108b, and 108c. However, the metal layer 102 is thinner at the periphery of the capping layer 104 at location 110 and location 112 where the capping layer 104 joins the sidewall of dielectric surface 108a and dielectric surface 108b, respectively. However, at locations 110 and 112, the capping layer and surrounding dielectric material at such locations is more prone to be damaged by exposure to oxygen from a subsequent vacuum break (e.g., exposure to atmosphere) or damaged due to exposure to fluorine during a subsequent W or Mo deposition process.

By use of the processes described herein, the deposited metal layer is able to form over regions of the dielectric surface, and thus is not constrained to form on the capping layer. For example, the partial selectivity deposition process can form products formed by metal (e.g., tungsten) deposition onto a capping layer and such products also tend to deposit onto adjacent dielectric surfaces that are in proximity to the metal (e.g., tungsten) deposition also occurring. Partially selective metal deposition processes of the present disclosure can be tunable (e.g., pressure, dosing, etc.) in order to promote such partially selective metal deposition onto the capping surface and adjacent dielectric surfaces.

The methods of the present disclosure can be effective for metal gapfill processes in general and may be used with other metal gapfill material besides molybdenum such as, for example, tungsten and the like. For the sake of brevity, examples discussed herein include gapfill processes that include molybdenum which are not meant to be limit the scope of the disclosure provided herein and thus can include materials other than molybdenum.

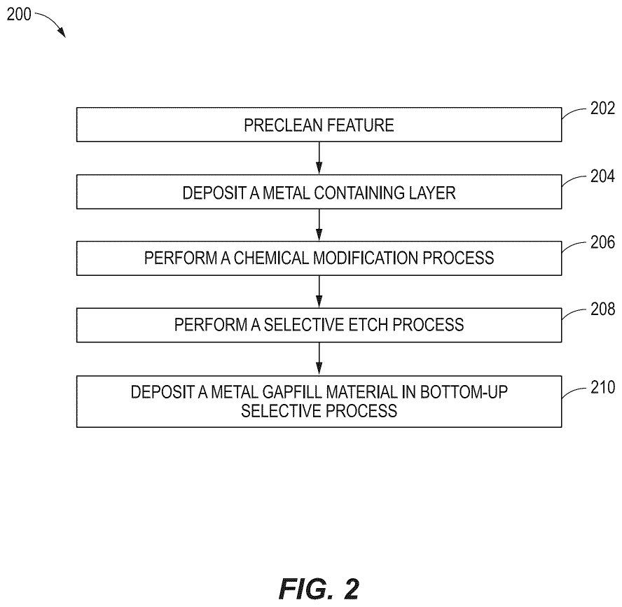

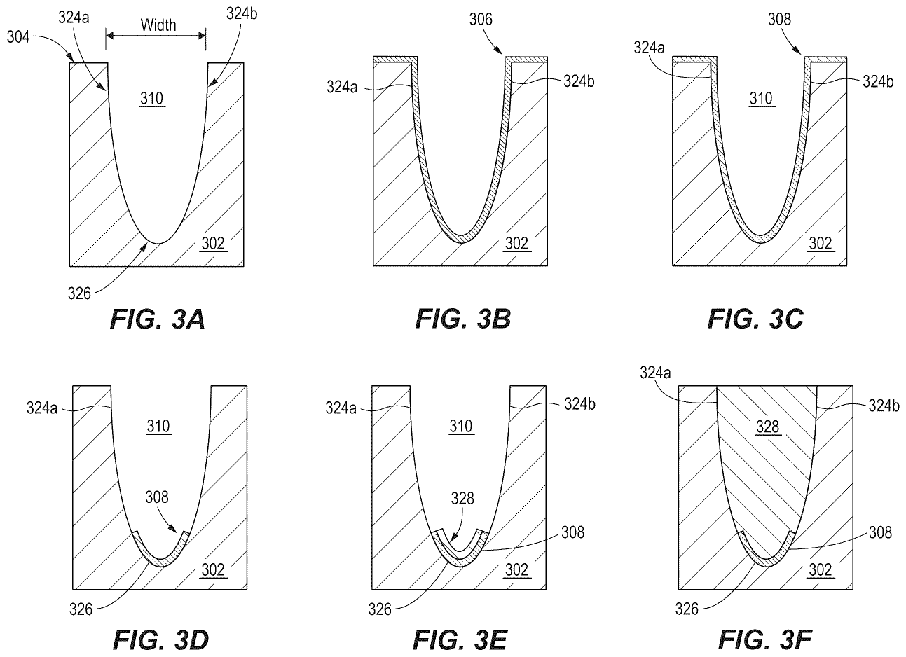

In the method 200 of FIG. 2, a selective CVD TiSi deposition and TiSi/Mo integration flow is shown. In the discussion of the method 200, references will be made to FIGS. 3A-3F. At operation 202, a preclean process is performed to remove any contaminates and/or oxidation from surfaces of a feature as depicted in FIG. 3A. The feature includes a cavity 310 of a substrate 302 formed of a dielectric material e.g., silicon dioxide, silicon nitride, etc. In some embodiments, the materials at the surface of the cavity 310 may be a silicon material or a silicon germanium (SiGe) material.

In one or more embodiments, cavities (e.g., vias, trenches, etc.) can have an average width. For example, the cavity 310 can have a width (shown in FIG. 3A) of about 35 nanometers (nm) or less, such as about 5 nm to about 35 nm, such as about 5 nm, 10 nm, and 15 nm to about 20 nm, 25 nm, 30 nm, or 35 nm. In one or more embodiments, cavities (e.g., vias) can have an average critical dimension of about 1 nanometer (nm) to about 20 nm. For example, the cavity 310 can have a critical dimension, e.g., a width between a first sidewall 324a and a second sidewall 324b of the features, of about 20 nanometers (nm) or less, such as about 1 nm to about 15 nm, such as about 1 nm, 5 nm, and 10 nm to about 12 nm, 15 nm, or 20 nm. Without being bound by theory, the present methods can allow for the deposition of a molybdenum gap fill material having no and/or reduced seams within the gap fill material. In one or more embodiments, cavity 310 can have an aspect ratio (depth: width) of about 1:1 to about 100:1, such as about 10:1, 15:1, or 25:1 to about 35:1, 45:1, or 50:1.

At operation 204, as shown in FIG. 3B, a deposition process is performed to produce a metal containing layer 306, such as a titanium containing layer, a molybdenum containing layer, and/or a tungsten containing layer, on the first sidewall 324a, the second sidewall 324b, and the bottom surface 326 of the cavity 310, as depicted in FIG. 3B. For example, the metal containing layer 306 includes a metal and a silicon containing material. For example, the metal containing layer 306 can include a titanium (Ti) layer and/or a TiSi layer. A TiSi layer can, for example, include a TiₓSi_{y} compound which may include Ti₅Si₃, TiSi₂, TiSi, or combinations thereof. The process includes depositing the titanium containing layer over a dielectric material layer formed on the substrate 302. In some embodiments, the deposition process is a CVD process, e.g., a plasma enhanced CVD process (PECVD). The deposition process can provide a thickness of metal layer of approximately 3 nm to approximately 9 nm on the first sidewall 324a, the second sidewall 324b, and/or the bottom surface 326. In some embodiments, the thickness of the metal containing layer 306 is conformal along the first sidewall 324a, the second sidewall 324b, and the bottom surface 326.

A TiSi deposition process can be performed using any suitable thermal or plasma enhanced CVD or ALD process. In some embodiments, the CVD or ALD process includes utilizing a plasma that includes precursors. A carrier gas may be utilized in the CVD or ALD process. The plasma/carrier gas may then be introduced towards the surface of the semiconductor substrate. In one or more embodiments, the carrier gas includes a noble gas, such as argon, neon, helium, or combinations thereof.

In one or more embodiments, deposition is performed by introducing a hydrogen-containing precursor by utilizing a capacitively coupled plasma (CCP) deposition process. In one or more embodiments, deposition includes introducing a hydrogen-containing precursor and a metal-containing precursor with the carrier gas. In one or more embodiments, the metal-containing precursor gas may be fluorine free to prevent formation of metal fluoride solids that have undesirable resistivity properties. For example, the hydrogen-containing precursor can include molecular hydrogen (H₂) and the metal-containing precursor is titanium chloride (TiCl₄). Without being bound by theory, the introduction of both the hydrogen-containing and the metal-containing precursors into the carrier gas causes both precursors to become energized on a molecular level to a point of at least partial disassociation in the carrier gas. For example, titanium chloride may disassociate into titanium-based ions (Ti⁺, TiClₓ⁺) or free radial titanium trichloride (TiCl₃^{*}); hydrogen may disassociate into hydronium ions (H⁺) or hydrogen free radicals (H*). The dissociated species may then interact with the silicon surface of the first sidewall 324a, the second sidewall 324b, and/or the bottom surface 326, donate electrons to the silicon atoms and then each species interact with one another and form the titanium silicide layer on the first sidewall 324a, the second sidewall 324b, and/or the bottom surface 326.

In one or more embodiments, the deposition is performed by maintaining the semiconductor substrate at a first metal deposition temperature. In one or more embodiments, the semiconductor substrate is maintained at a metal deposition temperature of about 200° C. to 800° C., such as about 200° C., 300° C., 400° C., 450° C., and 500° C. to about 600° C., 700° C., and 800° C., for a period of about 5 seconds to about 20 seconds, in which an inert gas may be present. The inert gas flowing over the semiconductor substrate may facilitate in cooling and affixing the deposition material (e.g., TiSi) on the top of the silicon-containing contact as well as removing volatilized products and unreacted materials, such as molecular hydrogen and hydrogen chloride (HCl).

Optionally, at operation 206, as shown in FIG. 3C, a chemical modification process is performed on the metal containing layer 306 to produce a nitrided layer 308, e.g., a TiN layer and/or a TiSiN layer. The chemical modification process can include a nitridation process via flowing a nitrogen based gas such as ammonia or N₂, a nitrogen radical such as an ammonia radical, and/or a nitrogen based compound such as ammonia over the metal containing layer 306 to convert the metal containing layer 306 into a nitrided layer 308. The chemical modification process can include flowing 500 sccm to about 6000 sccm of nitrogen gas, e.g., ammonia, over the metal containing layer 306.

At operation 208, as shown in FIG. 3D, a selective etch process is performed to remove a portion of the metal containing layer 306 and/or the nitrided layer 308, thereby exposing and/or etching the first sidewall 324a and/or the second sidewall 324b, as shown in FIG. 3D. At the end of operation 208 a portion of the metal containing layer formed during operation 206, such as a metal containing layer 306, will remain within a portion of the cavity 310 such as the bottom portion of the cavity 310. For example, the nitrided layer 308 can be selectively etched to expose a top portion of the first sidewall 324a and/or the second sidewall 324b. The top portion of the first sidewall 324a and/or the second sidewall 324b can include a depth of about 10% to about 90% of the depth of the cavity 310, relative to the top surface 304 of the substrate 302. For example, the top portion of the first sidewall 324a and/or the second sidewall 324 b can include about 80% of the depth of the cavity 310, relative to the top surface 304. The selective etch process selectively targets the metal containing layer 306 and/or the nitrided layer 308. The selective etch process includes flowing an etching gas and optional inert gas into the processing region. The etching gas can include chlorine or fluorine containing gas, or a combination thereof, wherein the etchant is selected to be reactive to the metal containing layer 306 and/or the nitrided layer 308, over the non-oxide metal, e.g., the substrate 302. In some embodiments, the etching gas may include MoCl₅, WF₆, WOCl₄, WO₂Cl₂, WCl₅, WCl₆, BCl₃, Cl₂, TiCl₄, SiCl₄, or other suitable compound. In one embodiment, the etching gas includes MoCl₅. In some embodiments, the selective etch process is performed at a pressure in a range from about 10 Torr to about 20 Torr, at a flow rate of argon gas into the processing region in a range from about 50 sccm to about 6000 sccm, at a flow rate of etchant gas into the processing region in a range from about 800 sccm to about 900 sccm, at a temperature in a range from about 0 degrees Celsius to about 250 degrees Celsius, and for a time period from about 4 seconds to about 120 seconds.

The selective etch process exposes the metal containing layer 306 and/or nitrided layer 308 to an etchant process to selectively remove the top portion of the metal containing layer 306 and/or nitrided layer 308 with minimal removal of the underlying substrate 302 and/or the bottom portion of the metal containing layer 306 and/or nitrided layer 308. The selective etch process may be a cyclic process. The selective etch process may be repeated for a number of cycles sufficient to reduce the thickness of the metal containing layer 306 and/or nitrided layer 308 from the initial thickness to a targeted reduced thickness and/or elimination. For example, the selective etch process may be repeated for 2 to 100 cycles, for example, 90 cycles. The selective etch process of operation 208 may be repeated until the top portion of the metal containing layer 306 and/or nitrided layer 308 are reduced and/or eliminated, thereby allowing only a bottom portion of the metal containing layer 306 and/or nitrided layer 308 to remain disposed over the bottom surface 326 of the cavity 310. The bottom portion includes about 10% to about 90% of the depth of the metal containing layer 306 and/or nitrided layer 308 disposed over the first sidewall 324a and/or the second sidewall 324b, relative to the bottom surface 326 of the substrate 302. The metal containing layer 306 and/or nitrided layer 308 remains along the bottom surface 326.

In an effort to selectively etch a metal containing layer to preferentially remove an upper region of the metal containing layer and leave a portion of the metal containing layer in a lower portion of a feature a “soak” type of etching process may be performed by introducing a hydrogen-containing precursor and a metal-containing precursor. The hydrogen-containing precursor can include molecular hydrogen (H₂) and the metal-containing precursor is molybdenum chloride (MoCl₅). Without being bound by theory, the introduction of both the hydrogen-containing and the metal-containing precursors into the carrier gas causes both precursors to become energized on a molecular level to a point of at least partial disassociation in the carrier gas. For example, molybdenum chloride may disassociate into molybdenum-based ions (Mo⁺, MoClₓ⁺) or free radial molybdenum trichloride (TiCl₄^{*}); hydrogen may disassociate into hydronium ions (H⁺) or hydrogen free radicals (H*). The dissociated species may then interact with the nitrided layer 308 and/or the metal containing layer 306 of the first sidewall 324a, the second sidewall 324b, and/or the bottom surface 326, to etch the nitrided layer 308 and/or the metal containing layer 306 of the first sidewall 324a, the second sidewall 324b, and/or the bottom surface 326.

In one or more embodiments, the etching process performed by introducing the metal-containing precursor for a period of about 200 seconds to about 300 seconds at a flow rate of about 800 sccm to about 1000 sccm. The processing chamber may be maintained at a pressure of about 10 Torr to about 20 Torr. The hydrogen-containing precursor may be introduced following the metal-containing precursor, in which the hydrogen-containing precursor is introduced for a period of about 80 seconds to about 100 seconds at a pressure of about 5 Torr to about 15 Torr. The use of the metal-containing precursor and the hydrogen-containing precursor may facilitate in etching the titanium-containing layer and/or nitrided layer from the first sidewall 324a, the second sidewall 324b, and/or the bottom surface 326.

The thickness of the metal containing layer 306 and/or nitrided layer 308 formed over the first sidewall 324a and/or the second sidewall 324b is reduced at a greater rate than a thickness of the metal containing layer 306 and/or nitrided layer 308 formed over the bottom surface 326 of the cavity 310.

At operation 210, a metal gap fill material 328 is deposited in a bottom-up selective deposition process (e.g., molybdenum based selective process (molybdenum over dielectric material of the sidewalls 324a, 324b of the cavity 310, etc.)) on the remaining metal containing layer 306 and/or nitrided layer 308 after the performance of operation 208, as shown in FIGS. 3E and 3F. The selective deposition process may deposit the metal gap fill material 328 along a top surface of the nitrided layer 308 prior to depositing along one or more of the sidewalls 324a, 324b, of the cavity 310. Without being bound by theory, a bottom-selective deposition process can prevent seams from forming in the metal gap fill material, thereby reducing resistance and increasing throughout during manufacturing processes.

In some embodiments, a conformal gap fill may be used instead of a bottom-up selective deposition process. In some embodiments, for example, the cavity 310 may be filled by conformal CVD using molybdenum or tungsten and the like. In some embodiments, a conformal molybdenum fill can be performed by using MoO₂Cl₂ or MoOCl₄+H₂ processes or a mixture of MoCl₅ with the aforementioned two precursors. Similarly, the structure fill can be done by a selective W bottom-up fill or conformal W fill process. In some embodiments, Mo and W materials can be interchanged or mixture of Mo and W used.

In an effort to maintain a conformal gap fill process, the bottom-up selective deposition process may be performed under conditions of a “soak” type etching process as described herein. The “soak” type etching process may allow for selective deposition of the gap fill material along the bottom portion of the cavity prior to deposition along the top portion of the sidewalls. The hydrogen-containing precursor can include molecular hydrogen (H₂) and the metal-containing precursor is molybdenum chloride (MoCl₅). Without being bound by theory, the introduction of both the hydrogen-containing and the metal-containing precursors into the carrier gas causes both precursors to become energized on a molecular level to a point of at least partial disassociation in the carrier gas. For example, molybdenum chloride may disassociate into molybdenum-based ions (Mo⁺, MoClₓ⁺) or free radial molybdenum trichloride (TiCl₄^{*}); hydrogen may disassociate into hydronium ions (H⁺) or hydrogen free radicals (H*). The dissociated species may then interact with the gap fill material of the first sidewall 324a, the second sidewall 324b, to etch the nitrided layer 308 and/or the metal containing layer 306 of the first sidewall 324a, the second sidewall 324b, selectively over the bottom surface.

In one or more embodiments, the gap fill process is performed at a pressure of about 40 Torr to about 60 Torr, a pedestal temperature of about 450° C., and an ampoule temperature of about 95° C. A purge gas, e.g., argon, and a processing gas, e.g., hydrogen, may be introduced to the processing chamber for a first period of time, e.g., about 10 seconds to about 20 seconds. The purge gas may be introduced to the processing chamber at a flow rate of about 5 slm to about 10 slm, and the processing gas may be introduced to the processing chamber at a flow rate of about 10 slm to about 20 slm. An etchant gas, e.g., MoCl₅, may be introduced to the processing chamber during a first portion of the first period of time, e.g., the first 2 seconds to the first 8 seconds. A second portion of the first period of time may include a rest period, in which the etchant gas is not introduced to the processing chamber. The process may be repeated for a plurality of cycles, e.g., about 80 cycles to about 100 cycles. Without being bound by theory, the gap fill process may allow for conformal gap fill process that reduces and/or eliminates seams within the gap fill material.

In FIG. 3F, a bottom-up metal gap fill material 328 has been deposited into cavity 310, thereby filling the cavity 310. The metal gap fill material 328 is shown in contact with the bottom portion of the metal containing layer 306 and/or nitrided layer 308 such that the metal gap fill material 328 covers the bottom portion and/or bottom surface 326 of the feature. The metal gap fill material 328 is also in contact with at least a portion of the sidewalls 324a, 324b.

In some embodiments, any suitable deposition process, including but not limited to CVD or ALD processes, may be utilized for the metal gap fill material process. The metal gap fill material may be applied such that the material is deposited onto the bottom portion of the device feature and then grown upwards towards the semiconductor field region such that the resultant gap fill material at least approaches the field region (as shown in FIG. 3F) or is at least partially level with the field region (not shown).

In one or more embodiments, the metal gap fill material includes one or more of cobalt (Co), molybdenum (Mo), tungsten (W), tantalum (Ta), titanium (Ti), ruthenium (Ru), rhodium (Rh), copper (Cu), iron (Fe), manganese (Mn), vanadium (V), niobium (Nb), hafnium (Hf), zirconium (Zr), yttrium (Y), aluminum (Al), tin (Sn), chromium (Cr), lanthanum (La), iridium (Ir), or any combination thereof. In one or more embodiments, the metal gap fill material includes tungsten (e.g., deposited using WF₆). In one or more embodiments, the conductor material includes molybdenum.

### Example Processing System

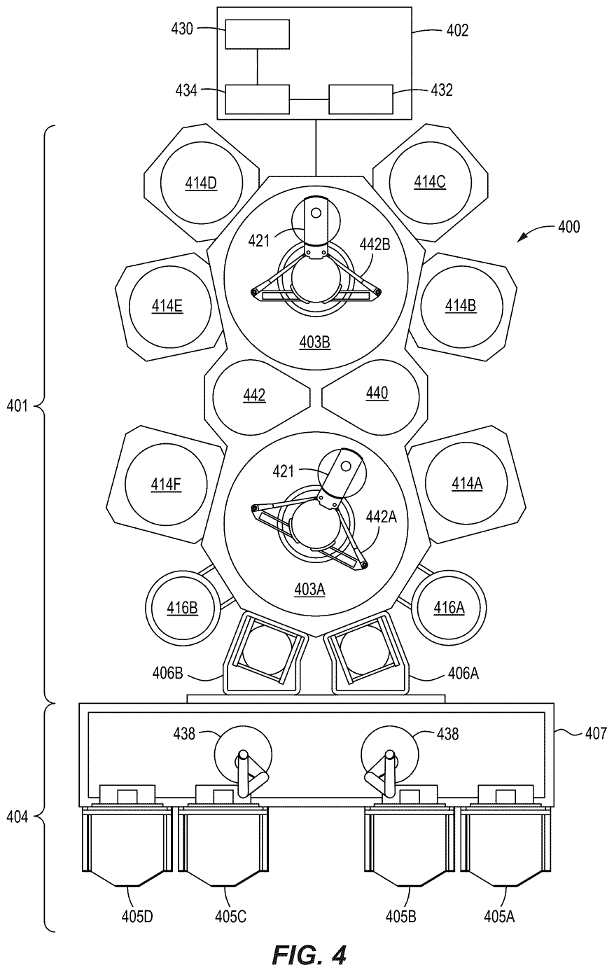

The methods of the present disclosure may be performed in individual process chambers that may be provided as part of a cluster tool, for example, the integrated tool 400 (e.g., cluster tool) described below with respect to FIG. 4. The advantage of using an integrated tool 400 is that there is no vacuum break between chambers and, therefore, no requirement to degas and pre-clean a substrate before treatment in a chamber. For example, in some embodiments the methods of the present disclosure may advantageously be performed in an integrated tool such that there are limited or no vacuum breaks between processes, limiting or preventing contamination of the substrate such as oxidation and the like. The integrated tool 400 includes a vacuum-tight processing platform 401, a factory interface 404, and a system controller 402. The vacuum-tight processing platform 401 comprises multiple processing chambers, such as 414A, 413B, 414C, 414D, 414E, and 414F operatively coupled to a vacuum substrate transfer chamber (transfer chambers 403A, 403B). The factory interface 404 is operatively coupled to the transfer chamber 403A by one or more load lock chambers (two load lock chambers, such as 406A and 406B shown in FIG. 4).

In some embodiments, the factory interface 404 comprises at least one docking station 407, at least one factory interface robot 438 to facilitate the transfer of the semiconductor substrates. The docking station 407 is configured to accept one or more front opening unified pod (FOUP). Four FOUPS, such as 405A, 405B, 405C, and 405D are shown in the embodiment of FIG. 4. The factory interface robot 438 is configured to transfer the substrates from the factory interface 404 to the vacuum-tight processing platform 401 through the load lock chambers, such as 406A and 406B. Each of the load lock chambers 406A and 406B have a first port coupled to the factory interface 404 and a second port coupled to the transfer chamber 403A. The load lock chamber 406A and 406B are coupled to a pressure control system (not shown) which pumps down and vents the load lock chambers 406A and 406B to facilitate passing the substrates between the vacuum environment of the transfer chamber 403A and the substantially ambient (e.g., atmospheric) environment of the factory interface 404. The transfer chambers 403A, 403B have vacuum robots 442A, 442B disposed in the respective transfer chambers 403A, 403B. The vacuum robot 442A is capable of transferring substrates 421 between the load lock chamber 406A, 406B, the processing chambers 414A and 414F and a cooldown station 440 or a pre-clean station 442. The vacuum robot 442B is capable of transferring substrates 421 between the cooldown station 440 or pre-clean station 442 and the processing chambers 414B, 414C, 414D, and 414E.

In some embodiments, the processing chambers 414A, 414B, 414C, 414D, 414E, and 414F are coupled to the transfer chambers 403A, 403B. The processing chambers 414A, 414B, 414C, 414D, 414E, and 414F may comprise, for example, preclean chambers, ALD process chambers, PVD process chambers, remote plasma chambers, CVD chambers, or the like. The chambers may include any chambers suitable to perform all or portions of the methods of the present disclosure, as discussed above, such as PVD W or PVD Mo chambers, CVD chambers, ALD chambers and the like. In some embodiments, one or more optional service chambers (shown as 416A and 416B) may be coupled to the transfer chamber 403A. The service chambers 416A and 416B may be configured to perform other substrate processes, such as degassing, orientation, substrate metrology, cool down, and the like.

The processing chambers 414A, 414B, 414C, 414D, 414E, and 414F may be any appropriate chamber for processing a substrate. In some examples, a processing chamber may be capable of performing an etch process, a cleaning process, an annealing process, a CVD deposition process, or an ALD deposition process. As used herein, CVD refers to chemical vapor deposition and ALD refers to atomic line deposition. In some embodiments, a processing chamber is a Selectra™ Etch chamber available from Applied Materials of Santa Clara, Calif. In some embodiments, a processing chamber is a SiCoNi™ Pre-clean chamber available from Applied Materials of Santa Clara, Calif. In some embodiments, a processing chamber may be a Centura™ Epi chamber, Volta™ CVD/ALD chamber, or Encore™ PVD chamber, all available from Applied Materials of Santa Clara, Calif.

The system controller 402 controls the operation of the tool 400 using a direct control of the process chambers 414A, 414B, 414C, 414D, 414E, and 414F or alternatively, by controlling the computers (or controllers) associated with the process chambers 414A, 414B, 414C, 414D, 414E, and 414F and the tool 400. In operation, the system controller 402 enables data collection and feedback from the respective chambers and systems to optimize performance of the tool 400. The system controller 402 generally includes a Central Processing Unit (CPU) 430, a memory 434, and a support circuit 432. The CPU 430 may be any form of a general-purpose computer processor that can be used in an industrial setting. The support circuit 432 is conventionally coupled to the CPU 430 and may comprise a cache, clock circuits, input/output subsystems, power supplies, and the like. Software routines, such as a method as described above may be stored in the memory 434 and, when executed by the CPU 430, transform the CPU 430 into a specific purpose computer (system controller). The software routines may also be stored and/or executed by a second controller (not shown) that is located remotely from the tool 400.

Overall, methods of the present disclosure can integrate multiple deposition and etching processes on the same integrated tool to achieve low contact resistance (Rc). Methods of the present disclosure provide middle-end-of-the-line (MEOL) contacts with reduced resistivity. Methods can integrate multiple MEOL processes on the same integrated tool as well as achieve low contact resistance (Rc). For example, a process has been developed that selectively etches a titanium silicon nitride layer by use of a selective etching process such that the deposition of a low resistance gap fill material is selective towards a bottom surface of the cavity, via, and/or trench, thereby reducing resistivity by preventing seam formation within the gap fill material.

While the foregoing is directed to embodiments of the present principles, other and further embodiments of the principles may be devised without departing from the basic scope thereof.

What is claimed is:

1. A method of forming a contact structure on a semiconductor substrate, comprising:
forming a metal layer on a surface of the contact structure by maintaining a first temperature of a substrate and providing a first carrier gas, a first metal-containing precursor, and a first hydrogen-containing precursor to a first deposition chamber, wherein:
the contact structure comprises a feature formed in a surface of the semiconductor substrate,
the feature comprises an opening that is defined by a bottom surface and sidewalls, which comprise a dielectric material, and
the metal layer is formed over the sidewalls and the bottom surface and the metal layer comprises a metal and a silicon containing material;
exposing the metal layer to a metal chloride containing precursor to remove a top portion of the metal layer from the sidewalls and surface of the semiconductor substrate; and
depositing a metal gap fill material over a portion of the metal layer remaining after exposing the metal layer to the metal chloride containing precursor to fill the feature formed in the surface of the semiconductor substrate.

2. The method of claim 1, wherein:
the first hydrogen-containing precursor is H₂,
the first metal-containing precursor is TiCl₄, and
the first temperature of the substrate is about 200 °C to 800 °C.

3. The method of claim 1, wherein the metal comprises titanium, tungsten, molybdenum, or combinations thereof.

4. The method of claim 1, wherein the metal comprises titanium.

5. The method of claim 1, wherein depositing the metal gap fill material comprises depositing the metal gap fill material using a chemical vapor deposition process.

6. The method of claim 5, wherein the chemical vapor deposition process is a bottom up fill process.

7. The method of claim 1, wherein exposing the metal layer to the metal chloride containing precursor comprises delivering the metal chloride containing precursor to the feature at a pressure of about 10 Torr to about 20 Torr.

8. The method of claim 7, wherein exposing the metal layer to the metal chloride containing precursor comprises delivering the metal chloride containing precursor to the feature at a flow rate of about 800 sccm to about 1000 sccm.

9. The method of claim 1, wherein depositing the metal gap fill material
comprises:
delivering a purge gas and a processing gas to the feature for a period of 10 seconds; and
delivering an etchant gas to the feature for 4 seconds of the period of 10 seconds.

10. The method of claim 9, wherein delivering the purge gas, the processing gas, and the etchant gas are repeated for 2 to 100 cycles.

11. A method of forming a contact structure on a semiconductor substrate, comprising:
forming a metal layer on a surface of the contact structure by maintaining a first temperature of a substrate and providing a first carrier gas, a first metal-containing precursor, and a first hydrogen-containing precursor to a first deposition chamber, wherein:
the contact structure comprises a feature formed in a surface of the semiconductor substrate,
the feature comprises an opening that is defined by a bottom surface and sidewalls, which comprise a dielectric material, and
the metal layer is formed over the sidewalls and the bottom surface and the metal layer comprises a metal and a silicon containing material;
exposing the metal layer formed over the sidewalls and bottom surface to a nitrogen containing plasma to cause a portion of the metal layer to form a nitrided layer;
exposing the nitrided layer to a metal chloride containing precursor to remove a top portion of the nitrided layer from the sidewalls and surface of the semiconductor substrate; and
depositing a metal gap fill material over the nitrided layer to fill the feature formed in the surface of the semiconductor substrate.

12. The method of claim 11, wherein:
the first hydrogen-containing precursor is H₂,
the first metal-containing precursor is TiCl₄, and
the first temperature of the substrate is about 200° C. to 800° C.

13. The method of claim 11, wherein the metal comprises titanium, tungsten, molybdenum, or combinations thereof.

14. The method of claim 11, wherein the metal comprises titanium.

15. The method of claim 11, wherein depositing the metal gap fill material comprises depositing the metal gap fill material using a chemical vapor deposition process.

16. The method of claim 15, wherein the chemical vapor deposition process is a bottom up fill process.

17. The method of claim 11, wherein exposing the nitrided layer to the metal chloride containing precursor comprises delivering the metal chloride containing precursor to the feature at a pressure of about 10 Torr to about 20 Torr.

18. The method of claim 17, wherein exposing the nitrided layer to the metal chloride containing precursor comprises delivering the metal chloride containing precursor to the feature at a flow rate of about 800 sccm to about 1000 sccm.

19. The method of claim 11, wherein depositing the metal gap fill material
comprises:
delivering a purge gas and a processing gas to the feature for a period of 10 seconds; and
delivering an etchant gas to the feature for 4 seconds of the period of 10 seconds.

20. The method of claim 19, wherein delivering the purge gas, the processing gas, and the etchant gas are repeated for 2 to 100 cycles.
